(19) United States
(12) Patent Application Publication
(10) Pub. No.: US 2009/0102515 A1
(43) Pub. Date: Apr. 23, 2009

(54) Sense-amplifying circuit having two amplification stages

(76) Inventor: Hisatada Miyatake, Shiga-ken (JP)

Correspondence Address: IBM CORPORATION, INTELLECTUAL PROPERTY LAW;DEPT 917, BLDG. 006-1, 3605 HIGHWAY 52 NORTH, ROCHESTER, MN, 55901-7829, US

(21) Appl. No.: 11/875,939

(22) Filed: Oct. 21, 2007

(51) Int. Cl. H03F 3/45

(52) U.S. Cl. 327/52

(57) ABSTRACT

A sense-amplifying circuit amplifies a voltage difference between a first signal source and a second signal source. A first inverter has a first intermediate node from which a first output extends. A second inverter has a second intermediate node from which a second output extends. The second inverter is recursively cross-coupled with the first inverter. A first power source switch connects the first and second inverters to a first power source line. A second power source switch connects the first and the second inverters to a second power source line. A first sense-amplifying switch connects the first signal source to the first intermediate node. A second sense-amplifying switch connects the second signal source to the second intermediate node. A first pre-charge switch connects the first intermediate node to the second power source line. A second pre-charge switch connects the second intermediate node to the second power source line.

### FIELD OF THE INVENTION

The present invention relates generally to a sense-amplifying circuit that amplifies the voltage difference between a first signal source and a second signal source. The present invention relates more particularly to such a sense-amplifying circuit that has two amplification stages.

### BACKGROUND OF THE INVENTION

A sense-amplifying circuit, which may also be referred to as a sense amplifier, is a circuit that amplifies the voltage difference between a first signal source and a second signal source. Typically, one of the signal sources is a reference signal source, and the other signal source is a variable signal source that is to be compared to the reference signal source. For instance, an example of such a variable signal source is an electrical fuse, or e-fuse. E-fuses are described in detail at en.wikipedia.org/wiki/EFUSE and www-306.ibm.com/chips/news/2004/0730_efuse.html, which are both Internet web sites.

FIG. 1 shows a conventional sense-amplifying circuit 100, according to the prior art. The circuit 100 amplifies the difference in the voltage across the e-fuse 102, which is a first signal source, as compared to the voltage across the reference resistor 104, which is a second signal source. This voltage difference is provided at the outputs 106 and 106′ For example, when the output 106 has a voltage level corresponding to a high logical value (e.g., such as logic one), the output 106′ has a voltage level corresponding to a low logical value (e.g., such as logic zero), and vice-versa. There is a first power source line 108 connected to the circuit 100, and a second power source line 110 connected to the circuit 100, where the second power source line 110 may be ground.

The circuit 100 includes a first inverter sub-circuit 112 and a second inverter sub-circuit 114 that are recursively cross-coupled with one another. The inverter sub-circuits 112 and 114 may also be referred to as inverters. The inverter sub-circuit 112 includes an inversely controlled switch 116 and a switch 118, and the inverter sub-circuit 114 includes an inversely controlled switch 120 and a switch 122. An inversely controlled switch is a switch that has its control gate oppositely coupled to an input signal, such that when the input signal is high, the switch is turned off, and when the input signal is low, the switch is turned on. This is compared to a non-inversely controlled switch, which has its controlled gate directly coupled to an input signal, such that when the input signal is high, the switch is turned on, and when the input signal is low, the switch is turned off. A first intermediate node 124 is defined between the switches 116 and 118, and a second intermediate node 126 is defined between the switches 120 and 122.

A first power source switch 128 connects the inverter sub-circuits 112 and 114 to the first power source line 108, and a second power source switch 130 connects the inverter sub-circuits 112 and 114 to the second power source line 110. The first power source switch 128 is inversely controlled by the opposite of a sense-amplifier set input 132, which is referred to as the input 132′, and the second power source switch 130 is controlled by the sense-amplifier set input 132. Thus, when the input 132 is high, the first power source switch 128 is on (because the input 132′ is low) and the second power source switch 130 is on, and when the input 132 is low, the first power source switch 128 is off (because the input 132′ is high) and the second power source switch 130 is off.

The circuit 100 includes source signal switches 134 and 136 that are always on via connection to the power source line 108. The source signal switch 134 connects the e-fuse 102 to a first switch pair 138 that is always connected to the power source line 108, and source signal switch 136 connects the reference resister 104 to a second switch pair 140 that is also always connected to the power source line 108. The first switch pair 138 includes an inversely controlled switch 144 and a switch 146 that define an intermediate node 147 connected to the intermediate node 124. The second switch pair 140 includes an inversely controlled switch 148 and a switch 150 that define an intermediate node 152 connected to the intermediate node 126.

The switches 144 and 148 are connected to the opposite of a pre-charge input, which is referred to as the input 154′, such that when the pre-charge input is high (such that the input 154′ is low), the switches 144 and 148 are on, and when the pre-charge input is low (such that the input 154′ is high), the switches 144 and 148 are off. The switches 146 and 150 are connected to a signal-on input 156, such that when the input 156 is high, the switches 146 and 150 are on, and when the input 156 is low, the switches 146 and 150 are off. Therefore, in the prior art sense-amplifying circuit 100, there are four inputs: the sense-amplifier-set input 132 and its opposite input 132′, the pre-charge opposite input 154′, and the signal-on input 156.

FIG. 1B shows how the inputs 132, 132′, 154′, and 156 are asserted to output the difference in voltage between the e-fuse 102 and the reference resistor 104, according to the prior art. The pre-charge opposite input 154′ is initially asserted low (i.e., the pre-charge input itself is initially asserted high). Thereafter, the signal-on input 156 is asserted high and the sense-amplifier-set input 132 is asserted low, the latter causing the opposite input 132′ to be asserted high. During this signal development stage 182, the difference in resistance between the e-fuse 102 and the reference resistor 104 is converted to voltage difference on the nodes 147 and 152. Then, the set input 132 is raised to high and at the same time the set-n input 132′ is fallen to low. After that the pre-charge opposite input 154′ is made off (raised to high) and the signal-on input 156 is also made off (fallen to low), and the output signals on output nodes 106 and 106′ are fully amplified to directions opposite each other.

Within the sense-amplifying circuit 100, the difference in resistance of both the e-fuse 102 and the reference resistor 104 appear as potentials on the nodes 124 and 126 during the signal development stage 182. The circuit 100 converts this difference in resistance into a difference in voltage by feeding current to both the fuse 102 and the resistor 104. It is desirable to maintain the transistors of the switches 144 and 148 as constant current sources, while maintaining the transistors of switches 146 and 150 as ideal switches (i.e., switches with resistances of zero as they are turned on). This is because it is desirable to input the same amount of current to both the e-fuse 102 and the reference resistor 104 to convert their resistances into voltages.

If each of the transistors of the switches 144 and 148 is to be used as a constant current source, the gate potential of each has to be appropriately controlled, which requires a dedicated circuit. Actually this is avoided by dropping the gate potential of each transistor to a ground potential, which makes the transistors 144 and 148 not operate as constant current sources. As an actual transistor has a resistance that changes depending on the operating region of the transistor, the circuit operation is influenced by the resistances of the transistors when the transistors are on. Specifically, the transistors of the switches 146 and 150 have source potentials that change according to the voltages over the e-fuse 102 and the reference resistor 104. Therefore, the voltage between the gate and the source of these transistors is not well controlled.

As such, in the sense-amplifying circuit 100, the resistance values of the e-fuse 102 and the reference resistor 104 are not simply converted into input voltages for sense amplification purposes, making it difficult to operate the sense amplifier 100 in a stable fashion realized with desired operating regions of the transistors within a somewhat wide power source voltage range (i.e., the voltage at the power source line 108). Moreover, the resistance of the e-fuse 102 can have a significant range of resistance variation, and the operating regions of the transistors of the switches 144 and 146 likewise change as the power source voltage (i.e., the voltage at the power source line 108) changes. For all of these reasons, it is difficult to operate the sense-amplifying circuit 100 under a low voltage power source of approximately 0.6 volts.

### SUMMARY OF THE INVENTION

The present invention relates generally to a sense-amplifying circuit having two amplification stages. The sense-amplifying circuit amplifies a voltage difference between a first signal source and a second signal source. In one embodiment, the sense-amplifying circuit includes a first inverter sub-circuit having a first intermediate node from which a first output of the sense-amplifying circuit is extended. The circuit includes a second inverter sub-circuit having a second intermediate node from which a second output of the sense-amplifying circuit is extended. The second inverter sub-circuit recursively cross-coupled with the first inverter sub-circuit.

The sense-amplifying circuit includes a first power source switch connecting the first and the second inverter sub-circuits to a first power source line. The circuit includes a second power source switch connecting the first and the second inverter sub-circuits to a second power source line. The circuit also includes a first sense-amplifying switch connecting the first signal source to the first intermediate node, and a second sense-amplifying switch connecting the second signal source to the second intermediate node. The sense-amplifying circuit further includes a first pre-charge switch connecting the first intermediate node to the second power source line, and a second pre-charge switch connecting the second intermediate node to the second power source line.

In one embodiment, the sense-amplifying circuit is operable in both a first amplification stage and a second amplification stage. In the first amplification stage, just the first inversely controlled switch of the first inverter sub-circuit, the second inversely controlled switch of the second inverter sub-circuit, the first power source switch, and the first and the second sense-amplifying switches are used. In the second amplification stage, just the first inversely controlled switch and the first switch of the first inverter sub-circuit, the second inversely controlled switch and the second switch of the second inverter sub-circuit, and the first and the second power source switches are used.

A method of one embodiment thus amplifies the voltage difference between the first signal source and the second signal source using the sense-amplifying circuit. A pre-charge input of the sense-amplifying circuit is asserted high. The first power source switch is inversely controlled by the pre-charge input. The first and the second pre-charge switches are also controlled by the pre-charge input. The pre-charge input is then asserted low. The circuit is operated in the first amplification stage by asserting a sense-amplifier-set input of the sense-amplifying circuit low and a signal-on input of the sense-amplifying circuit high. The second power source switch is controlled by the sense-amplifier-set input, and the first and the second sense-amplifying switches are controlled by the signal-on input. The circuit is then operated in the second amplification stage by asserting the sense-amplifier-set input high and the signal-on input low.

Other aspects and embodiments of the invention will become apparent by reading this detailed description, and by referring to the accompanying drawings.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1A is a diagram of a sense-amplifying circuit, according to the prior art.

FIG. 1B is a timing diagram of the sense-amplifying circuit of FIG. 1A, according to the prior art.

FIG. 2 is a diagram of a sense-amplifying circuit, according to an embodiment of the invention.

FIG. 3 is a timing diagram of the sense-amplifying circuit of FIG. 2 to enter a first amplification stage, according to an embodiment of the invention.

FIG. 4 is a diagram of the sense-amplifying circuit of FIG. 2 when it operates in the first amplification stage of FIG. 3, according to an embodiment of the invention.

FIG. 5 is a timing diagram of the sense-amplifying circuit of FIG. 2 to enter a second amplification stage after having operated in the first amplification stage of FIG. 3, according to an embodiment of the invention.

FIG. 6 is a diagram of the sense-amplifying circuit of FIG. 2 when it operates in the second amplification stage of FIG. 5, according to an embodiment of the invention.

FIG. 7 is a flowchart of a method to control the sense-amplifying circuit of FIG. 2, according to an embodiment of the invention.

### DETAILED DESCRIPTION OF THE DRAWINGS

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

### Sense-Amplifying Circuit

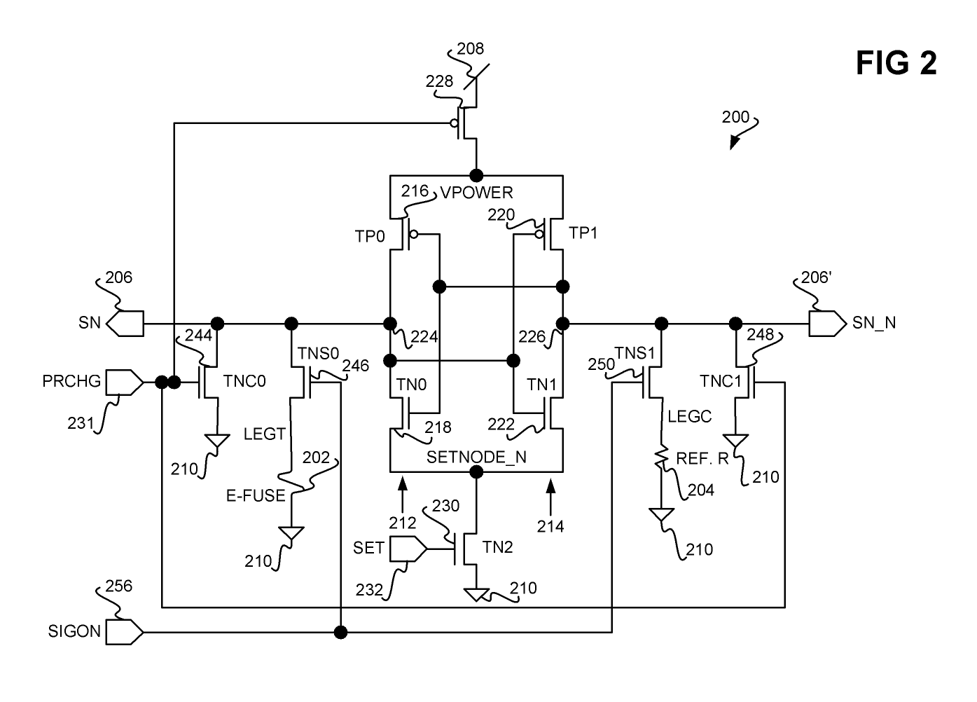

FIG. 2 shows a sense-amplifying circuit 200, according to an embodiment of the invention. The circuit 200 amplifies the difference in the voltage across the e-fuse 202, which is a first signal source, as compared to the voltage across the reference resistor 204, which is a second signal source. This voltage difference is provided at the outputs 206 and 206′. For example, when the output 206 has a voltage level corresponding to a high logical value (e.g., such as logic one), the output 206′ has a voltage level corresponding to a low logical value (e.g., such as logic zero), and vice-versa. There is a first power source line 208 connected to the circuit 200, and a second power source line 210 connected to the circuit 200, where the second power source line 210 may be ground.

The circuit 200 includes a first inverter sub-circuit 212 and a second inverter sub-circuit 214 that are recursively cross-coupled with one another. The inverter sub-circuits 212 and 214 may also be referred to as inverters. The inverter sub-circuit 212 includes an inversely controlled switch 216 and a switch 218, and the inverter sub-circuit 214 includes an inversely controlled switch 220 and a switch 222. An inversely controlled switch is a switch that has its control gate oppositely coupled to an input signal, such that when the input signal is high, the switch is turned off, and when the input signal is low, the switch is turned on. This is compared to a non-inversely controlled switch, which has its controlled gate directly coupled to an input signal, such that when the input signal is high, the switch is turned on, and when the input signal is low, the switch is turned off. A first intermediate node 224 is defined between the switch 216 and 218, and a second intermediate node 226 is defined between the switches 220 and 222.

The inverter sub-circuits 212 and 214 are recursively cross-coupled with one another as follows. The intermediate node 224 of the first inverter sub-circuit 212 is connected to the control gates of the switches 220 and 222 of the second inverter sub-circuit 214. Likewise, the intermediate node 226 of the second inverter sub-circuit 214 is connected to the control gates of the switches 216 and 218 of the first inverter sub-circuit 212. This type of connection is what is meant by the inverter sub-circuits 212 and 214 being recursively cross-coupled in at least one embodiment of the invention.

A first power source switch 228 connects the inverter sub-circuits 212 and 214 to the first power source line 208, and a second power source switch 230 connects the inverter sub-circuits 212 and 214 to the second power source line 210. The first power source switch 228 is inversely controlled by a pre-charge input 231, and the second power source switch 230 is controlled by a sense-amplifier-set input 232. Thus, when the input 231 is high, the first power source switch 228 is off, and when the input 231 is low, the first power source switch 228 is on. By comparison, when the input 232 is high, the second power source switch 230 is on, and when the input 232 is off, the second power source switch 230 is off.

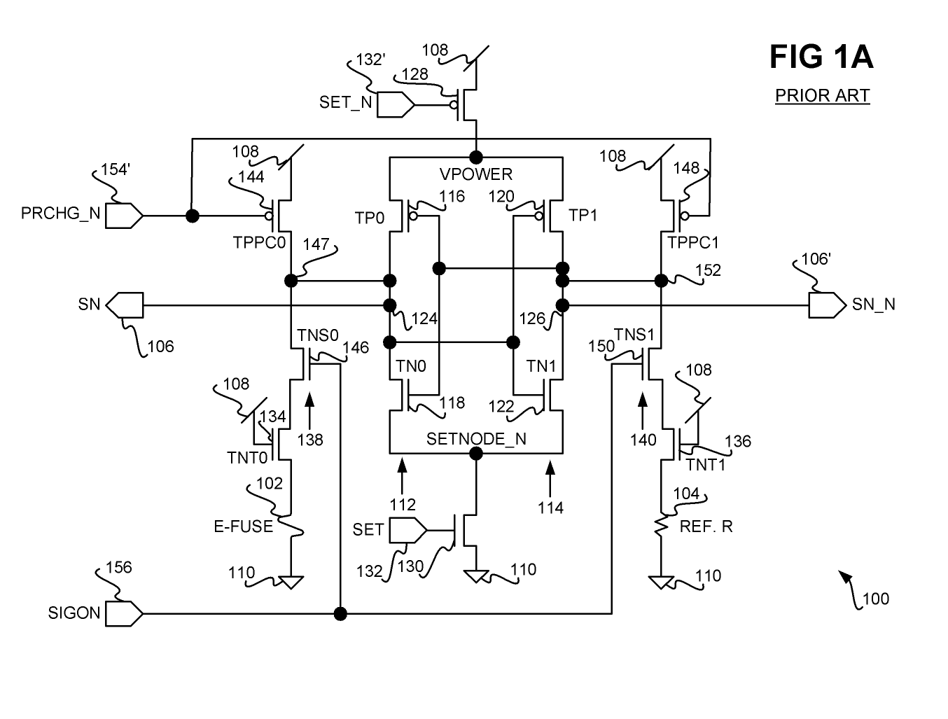

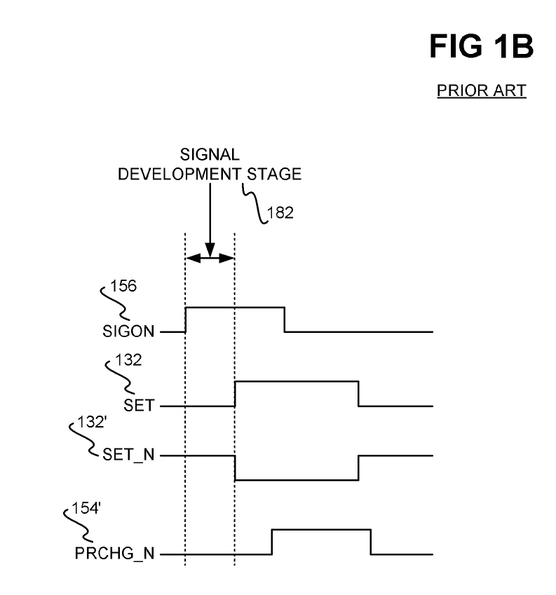

A first sense-amplifying switch 246 connects the e-fuse 202 to the first intermediate node 224 of the first inverter sub-circuit 212, and a second sense-amplifying switch 250 connects the reference resistor 204 to the second intermediate node 226 of the second inverter sub-circuit 214. The sense-amplifying switches 246 and 250 are controlled by a signal-on input 256. As such, when the signal-on input 256 is high, the sense-amplifying switches 246 and 250 are on, and when the signal-on input 256 is low, the sense-amplifying switches 246 and 250 are off. In one embodiment, the sense-amplifying circuit 200 may include source signal switches, similar to the source signal switches 134 and 136 of FIG. 1A, in-between the switches 246 and 250 and the e-fuse 202 and the reference resistor 204.

A first pre-charge switch 244 connects the first intermediate node 224 of the first inverter sub-circuit 212 to the second power source line 210, and a second pre-charge switch 248 connects the second intermediate node 226 of the second inverter sub-circuit 214 to the second power source line 210. The pre-charge switches 244 and 248 are controlled by the pre-charge input 231. As such, when the pre-charge input 231 is high, the pre-charge switches 244 and 248 are on, and when the pre-charge input 231 is low, the pre-charge switches 244 and 248 are off. Thus, in the sense-amplifying circuit 200, there are three inputs: the pre-charge input 231, the sense-amplifier-set input 232, and the signal-on input 256.

It is noted that in one embodiment, the switches 216, 218, 220, 222, 228, 230, 244, 246, 248, and 250 of the sense-amplifying circuit 200 may be implemented as transistors. An example of such a transistor is a metal-oxide semiconductor field-effect transistor (MOSFET). However, in other embodiments, other types of transistors and/or other types of switches may be used to implement the switches 216, 218, 220, 222, 228, 230, 244, 246, 248, and 250.

### First Amplification Stage

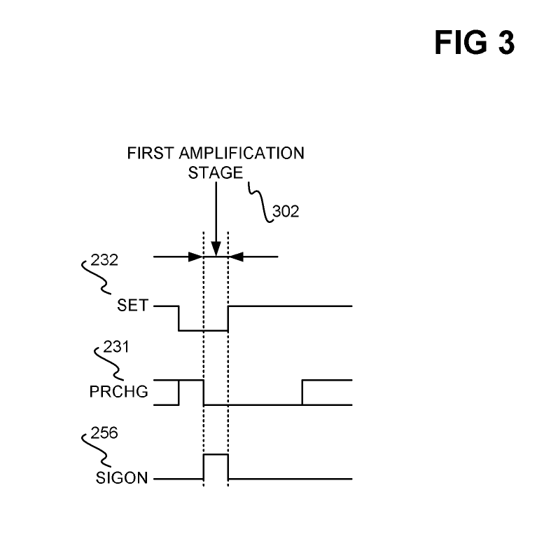

FIG. 3 shows how the inputs 231, 232, and 256 of the sense-amplifying circuit 200 are asserted within a first amplification stage 302, according to an embodiment of the invention. The pre-charge input 231, prior to entry in the first amplification stage 302, is asserted high. Thereafter, the pre-charge input 231 is asserted low, the sense-amplifier-set input 232 is asserted low, and the signal-on input 256 is asserted high.

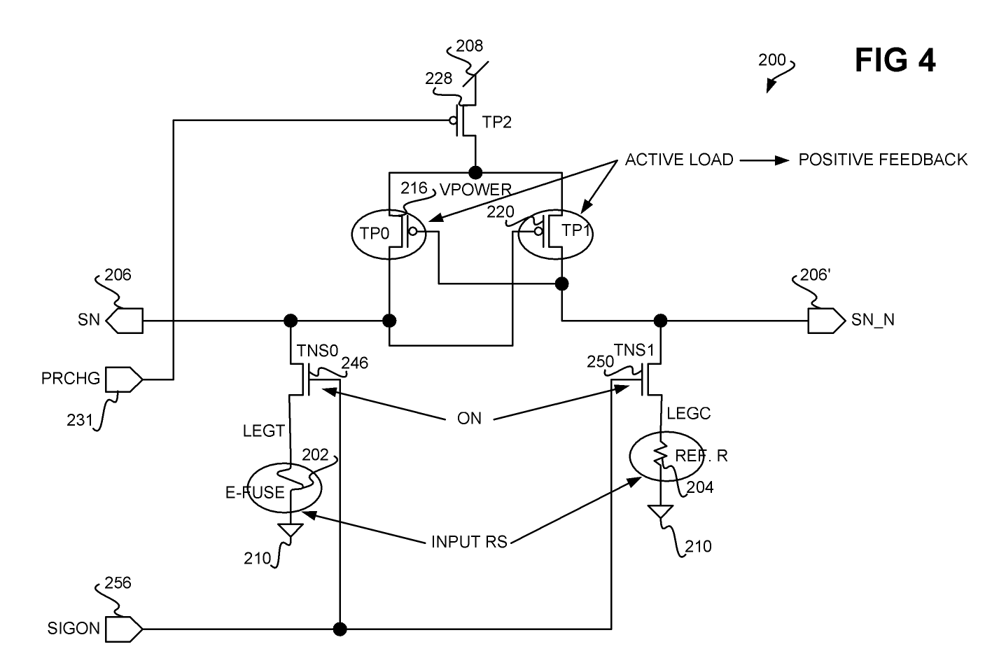

FIG. 4 shows the sense-amplifying circuit 200 when it operates in the first amplification stage 302, according to an embodiment of the invention. The components of the circuit 200 that are not involved in operation of the circuit 200 in the first amplification stage 302 are not shown in FIG. 4 for illustrative clarity. Thus, just the components of the circuit 200 that are involved in operation of the circuit 200 in the first amplification stage 302 are shown in FIG. 4.

The switches 228, 246, and 250 are on in the first amplification stage 302. Therefore, power from the power source line 208 is provided to the switches 216 and 220 through the switch 228. Likewise, the e-fuse 202 and the reference resistor 204 are connected to the switches 216 and 220 through the switches 246 and 250. As such, the switch 216 is connected to the e-fuse 202, which is connected to the second power source line 210, and the switch 220 is connected to the reference resistor 204, which is connected to the second power source line 210 as well.

In the first amplification stage 302, the difference between the voltage over the e-fuse 202 and the voltage over the reference resistor 204 is amplified by some amount, and appears at the outputs 206 and 206′. Because there is an active load on the switches 216 and 220, positive feedback (i.e., amplification) of the difference between the voltage over the e-fuse 202 and the voltage over the reference resistor 204 is provided at the outputs 206 and 206′.

More specifically, the switches 216 and 220 function as active loads to the e-fuse 202 and the reference resistor 204. When the resistance of the e-fuse 202 is larger than the resistance of the reference resistor 204, the potential at the output 206 is high, making the potential at the output 206′ low. Accordingly, the positive feedback functions so that the current through the switch 216 becomes larger and the potential at the output 206 becomes greater, such that the circuit 200 operates as an amplifier. Unlike the conventional circuit 100 of FIG. 1, the circuit 200 provides such positive potential feedback as has been described.

### Second Amplification Stage

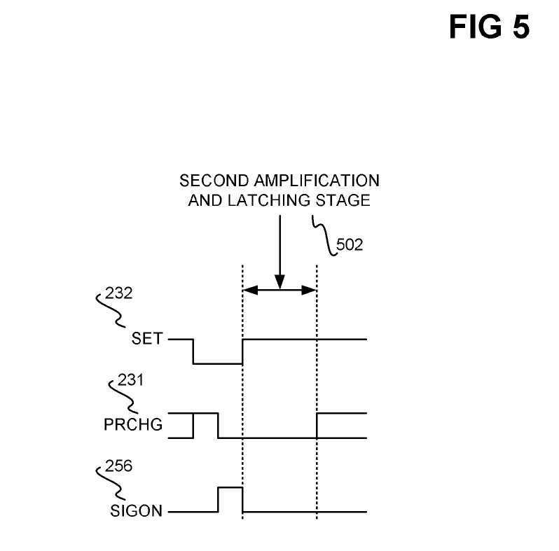

FIG. 5 shows how the inputs 231, 232, and 256 of the sense-amplifying circuit 200 are asserted within a second amplification stage 502, after the first amplification stage 302 has been entered, according to an embodiment of the invention. The second amplification stage 302 may be referred to as a second amplification and latching stage. The pre-charge input 231 is still asserted low, as in the first amplification stage 302. The sense-amplifier-set input 232 is asserted high, after having been asserted low in the first amplification stage 302, and the signal-on input 256 is asserted low, after having been asserted high in the first amplification stage 302.

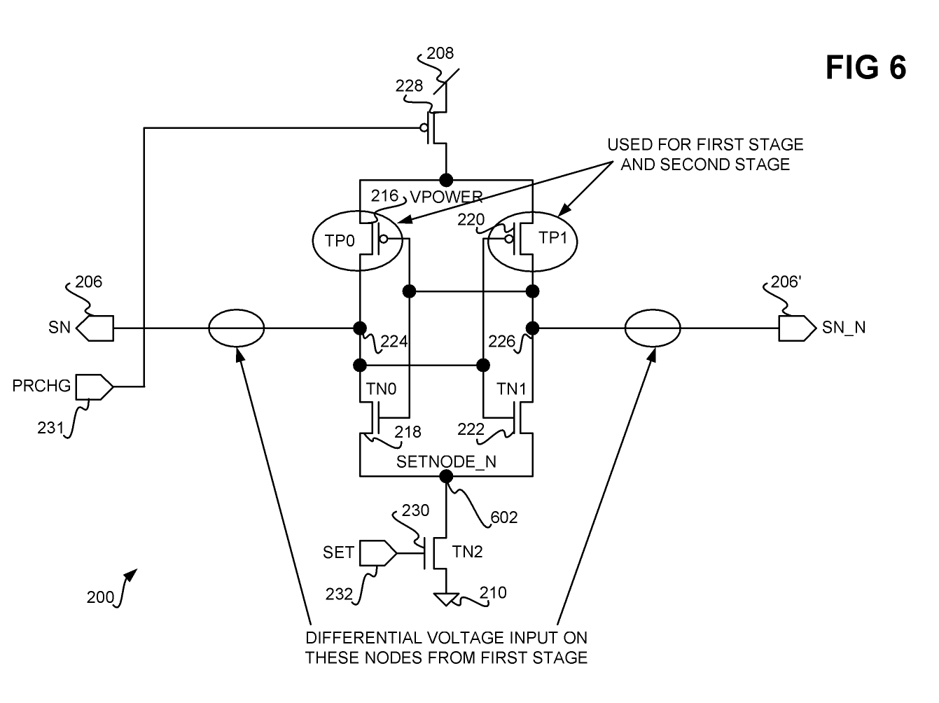

FIG. 6 shows the sense-amplifying circuit 200 when it operates in the second amplification stage 502, according to an embodiment of the invention. The components of the circuit 200 that are not involved in operation of the circuit 200 in the second amplification stage 502 are not shown in FIG. 6 for illustrative clarity. Thus, just the components of the circuit 200 that are involved in operation of the circuit 200 in the second amplification stage 502 are shown in FIG. 6.

The switches 228 and 230 are on in the second amplification stage 502. Therefore, power from the power source line 208 is provided to the switches 216 and 220 through the switch 228. Similarly, the power source line 210 is connected to the switches 218 and 222 through the switch 230. As such, the power source line 208 is connected to the switches 216 and 220, which are connected to the switches 218 and 222 respectively, which are connected to the second power source line 210.

In the second amplification stage 502, the voltages previously provided on the outputs 206 and 206′ in the first amplification stage 302 are amplified further. Thus, it can be said that the difference between the voltage over the e-fuse 202 and the voltage over the reference resistor 204 that was amplified by some amount in the first amplification stage 302 are amplified even more in the second amplification stage 502.

It is noted that the switches 216 and 220 are employed in both the first amplification stage 302 and the second amplification stage 502. This makes the size of the sense amplifier small for a two-stage amplifier. By comparison, the switches 218 and 222 are employed in just the second amplification stage 502, while the switches 246 and 250 are employed in just the first amplification stage 302. As such, the e-fuse 202 and the reference resistor 204 are connected in the first amplification stage 302, and the switches 218 and 222 are connected in the second amplification stage 502. The first amplification stage 302 provides the initial amplified potentials on the outputs 206 and 206′, which are then further magnified (i.e., amplified) in the second amplification stage 502.

Furthermore, the switch 228 acts as a simple switch in the first amplification stage 302. Accordingly the switch 228 can be large enough to supply big enough current in the first amplification stage 302. On the other hand, the switch 230 is used only for the dynamic cross-couple amplifier made of inverters 212 and 214 in the second amplification stage 502, and does not operate in the first amplification stage 302. Therefore, this transistor can be provided with optimal driving power to avoid a rapid drop in the potential of the node 602 so that the sense-amplifying circuit 200 operates in a stable manner. Thus, the switch 230 can be a transistor of relatively small size. When the second amplification stage 502 starts, the potentials at the outputs 206 and 206′ have already been provided by the first amplification stage 302, such that the circuit 200 stably and rapidly amplifies these potentials.

It is further noted that after the second amplification stage 502, the high output of the outputs 206 and 206′ is at the same potential as the power source line 208, and the low output of these outputs is at the same potential as the power source line 210, such as ground. Therefore, no current is consumed by the sense-amplifying circuit 200 after the second amplification stage 502 has stabilized. Furthermore, so long as the sense-amplifier-set input 232 is maintained high, the pre-charge input 231 is maintained low, and the signal-on input 256 is maintained low, the outputs 206 and 206′ are likewise maintained. As such, the sense-amplifying circuit 200 operates as a latch, which can be desirably convenient in some applications.

After the second amplification stage 502, the input signal source—i.e., the e-fuse 202 and the reference resistor—can be disconnected from the sense-amplifying circuit 200 while the signal-on input 256 is low. Thereafter, if a switch like the switch 134 of FIG. 1A is employed to connect and disconnect the input signal source to the circuit 200, a different input signal source can be connected to the circuit 200 immediately. As such, the cycle time for sense-amplification can be shortened to increase the throughput of the system that uses the sense amplifier. This is true also when FET's (field-effect transistors) are used as the input signal devices instead of the e-fuse and the reference resistor, and differential input signals are applied to the gates of those FET's. Note that the input signal devices have only to be equivalent to resistors, and have not necessarily to be real resistors.

Also after the second amplification stage 502, to return the sense-amplifying circuit 200 to a standby state, or the pre-charge state, just the pre-charge input 231 has to be asserted high. As such, the switch 228 is turned off, and the switches 244 and 248 are turned on to make the outputs 206 and 206′ both be at a low level. Because no current is fed into the sense-amplifying circuit 200 in this state, no power is consumed. The signal-on input 256 and the sense-amplifier-set input 232 may be asserted low or high in this standby or pre-charge state. Thus, the sense amplifier does not require strict or rigid controls.

Whereas, in FIG. 3, the timing of the high-to-low transition of the pre-charge input 231 is described as the same timing of the low-to-high transition of the signal-on input 256, these timings can be different; the high-to-low transition of the pre-charge input 231 can be after the low-to-high transition of the signal-on input 256. Also, the timing of the high-to-low transition of the signal-on input 256 can be after the low-to-high transition of the sense-amplifier-set input 232. The former can be before the latter so long as the differential signal at the nodes 224 and 226 stays large enough to be amplified by the low-to-high transition of the sense-amplifier-set input 232. Thus, the sense amplifier is operable with relaxed timing requirements. In this sense, too, the sense amplifier does not require strict controls.

### Summarizing Method and Conclusion

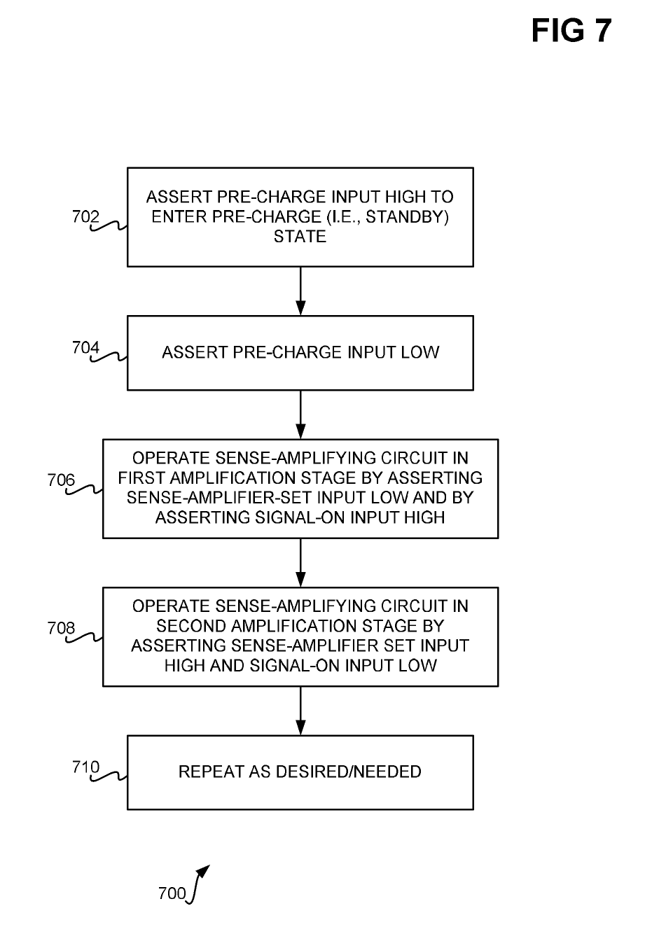

FIG. 7 shows a method 700 that summarizes how the sense-amplifying circuit 200 can be operated, according to an embodiment of the invention. The pre-charge input 231 is initially asserted high to enter a pre-charge, or standby, state (702). Thereafter, the pre-charge 231 input is asserted low. The sense-amplifying circuit 200 is then operated in the first amplification stage 302 by asserting the sense-amplifier-set input 232 low and the signal-on input 256 high (706). Thereafter, the circuit 200 is operated in the second amplification stage 502 by asserting the sense-amplifier-set input 232 high and the signal-on input 256 low (708). The method 700 can be repeated at part 702 as needed or desired (710), such as in relation to different input signal sources such as different e-fuses.

It is noted that, although specific embodiments have been illustrated and described herein, it will be appreciated by those of ordinary skill in the art that any arrangement calculated to achieve the same purpose may be substituted for the specific embodiments shown. This application is thus intended to cover any adaptations or variations of embodiments of the present invention. Therefore, it is manifestly intended that this invention be limited only by the claims and equivalents thereof.

We claim:

1. A sense-amplifying circuit to amplify a voltage difference between a first signal source and a second signal source, comprising:
a first inverter sub-circuit having a first intermediate node from which a first output of the sense-amplifying circuit is extended;
a second inverter sub-circuit having a second intermediate node from which a second output of the sense-amplifying circuit is extended, the second inverter sub-circuit recursively cross-coupled with the first inverter sub-circuit;
a first power source switch connecting the first and the second inverter sub-circuits to a first power source line;
a second power source switch connecting the first and the second inverter sub-circuits to a second power source line;
a first sense-amplifying switch connecting the first signal source to the first intermediate node;
a second sense-amplifying switch connecting the second signal source to the second intermediate node;
a first pre-charge switch connecting the first intermediate node to the second power source line; and,
a second pre-charge switch connecting the second intermediate node to the second power source line.

2. The sense-amplifying circuit of claim 1, wherein:
the first power source switch is inversely controlled by a pre-charge input of the sense-amplifying circuit;
the second power source switch is controlled by a sense-amplifier-set input of the sense-amplifying circuit;
the first and the second sense-amplifying switches are controlled by a signal-on input of the sense-amplifying circuit; and,
the first and the second pre-charge switches are controlled by the pre-charge input.

3. The sense-amplifying circuit of claim 2, wherein the sense-amplifying circuit is adapted to operate in both a first amplification stage and a second amplification stage.

4. The sense-amplifying circuit of claim 3, wherein the sense-amplifying circuit operates in the first amplification stage when, after the pre-charge input has been asserted high and thereafter is asserted low:
the sense-amplifier-set input is asserted low; and,
the signal-on input is asserted high.

5. The sense-amplifying circuit of claim 4, wherein the sense-amplifying circuit operates in the second amplification stage after the sense-amplifying circuit has operated in the first amplification stage when:
the sense-amplifier-set input is asserted high; and,
the signal-on input is asserted low.

6. The sense-amplifying circuit of claim 1, wherein the first inverter sub-circuit comprises:
a first inversely controlled switch connected to the first intermediate node; and,
a first switch connected to the first intermediate node,
wherein an input of the first inversely controlled switch is connected to an input of the first switch.

7. The sense-amplifying circuit of claim 6, wherein the second inverter sub-circuit comprises:
a second inversely controlled switch connected to the second intermediate node; and,
a second switch connected to the second intermediate node,
wherein an input of the second inversely controlled switch is connected to an input of the second switch.

8. The sense-amplifying circuit of claim 7, wherein the second inverter sub-circuit is recursively cross-coupled with the first inverter sub-circuit in that:
the inputs of the first inversely controlled switch and the first switch are connected to the second intermediate node; and,
the inputs of the second inversely controlled switch and the second switch are connected to the first intermediate node.

9. The sense-amplifying circuit of claim 1, wherein each of the first power source switch, the second power source switch, the first sense-amplifying switch, the second sense-amplifying switch, the first pre-charge switch, and the second pre-charge switch comprises a transistor.

10. The sense-amplifying circuit of claim 1, wherein the first signal source is an electrical fuse and the second signal source is a reference signal source.

11. A sense-amplifying circuit to amplify a voltage difference between a first signal source and a second signal source, comprising:
a first inverter sub-circuit and a second inverter sub-circuit recursively cross-coupled with one another,
the first inverter sub-circuit having a first intermediate node connecting a first inversely controlled switch of the first inverter sub-circuit to a first switch of the first inverter sub-circuit,
the second inverter sub-circuit having a second intermediate node connecting a second inversely controlled switch of the second inverter sub-circuit to a second switch of the second inverter sub-circuit;
a first power source switch connecting the first and the second inverter sub-circuits to a first power source line and a second power source switch connecting the first and the second inverter sub-circuits to a second power source line; and,
a first sense-amplifying switch connecting the first signal source to the first intermediate node and a second sense-amplifying switch connecting the second signal source to the second intermediate node,
wherein the sense-amplifying circuit is operable in both a first amplification stage and a second amplification stage,
wherein in the first amplification stage, just the first inversely controlled switch of the first inverter sub-circuit, the second inversely controlled switch of the second inverter sub-circuit, the first power switch, and the first and the second sense-amplifying switches are used, and
wherein in the second amplification stage, just the first inversely controlled switch and the first switch of the first inverter sub-circuit, the second inversely controlled switch and the second switch of the second inverter sub-circuit, and the first and the second power switches are used.

12. The sense-amplifying circuit of claim 11, wherein a first output of the sense-amplifying circuit extends from the first intermediate node and a second output of the sense-amplifying circuit extends from the second intermediate node.

13. The sense-amplifying circuit of claim 11, further comprising a first pre-charge switch connecting the first intermediate node to the second power source line and a second pre-charge switch connecting the second intermediate node to the second power source line.

14. The sense-amplifying circuit of claim 13, wherein:
the first power source switch is inversely controlled by a pre-charge input of the sense-amplifying circuit;
the second power source switch is controlled by a sense-amplifier-set input of the sense-amplifying circuit;
the first and the second sense-amplifying switches are controlled by a signal-on input of the sense-amplifying circuit; and,
the first and the second pre-charge switches are controlled by the pre-charge input.

15. The sense-amplifying circuit of claim 14, wherein the sense-amplifying circuit operates in the first amplification stage when, after the pre-charge input has been asserted high and thereafter is asserted low:
the sense-amplifier-set input is asserted low; and,
the signal-on input is asserted high.

16. The sense-amplifying circuit of claim 14, wherein the sense-amplifying circuit operates in the second amplification stage after the sense-amplifying circuit has operated in the first amplification stage when:
the sense-amplifier-set input is asserted high; and,
the signal-on input is asserted low.

17. The sense-amplifying circuit of claim 13, wherein each of the first power source switch, the second power source switch, the first sense-amplifying switch, the second sense-amplifying switch, the first pre-charge switch, and the second pre-charge switch comprises a transistor.

18. A method for amplifying a voltage difference between a first signal source and a second signal source using a sense-amplifying circuit, comprising:
asserting a pre-charge input of the sense-amplifying circuit high, the sense-amplifying circuit comprising:
a first inverter sub-circuit and a second inverter sub-circuit recursively cross-coupled with one another, the first inverter sub-circuit having a first intermediate node connecting a first inversely controlled switch of the first inverter sub-circuit to a first switch of the first inverter sub-circuit, the second inverter sub-circuit having a second intermediate node connecting a second inversely controlled switch of the second inverter sub-circuit to a second switch of the second inverter sub-circuit;
a first power source switch connecting the first and the second inverter sub-circuits to a first power source line and a second power source switch connecting the first and the second inverter sub-circuits to a second power source line, the first power source switch inversely controlled by the pre-charge input; and,
a first sense-amplifying switch connecting the first signal source to the first intermediate node and a second sense-amplifying switch connecting the second signal source to the second intermediate node;
a first pre-charge switch connecting the first intermediate node to the second power source line and a second pre-charge switch connecting the second intermediate node to the second power source line, the first and the second pre-charge switches controlled by the pre-charge input;
asserting the pre-charge input low;
operating the sense-amplifying circuit in a first amplification stage by asserting a sense-amplifier-set input of the sense-amplifying circuit low and a signal-on input of the sense-amplifying circuit high,
the second power source switch controlled by the sense-amplifier-set input, and the first and the second sense-amplifying switches controlled by the signal-on input; and,
operating the sense-amplifying circuit in a second amplification stage by asserting the sense-amplifier-set input high and the signal-on input low.

19. The method of claim 18, wherein a first output of the sense-amplifying circuit extends from the first intermediate node and a second output of the sense-amplifying circuit extends from the second intermediate node.

20. The method of claim 18, wherein each of the first power source switch, the second power source switch, the first sense-amplifying switch, the second sense-amplifying switch, the first pre-charge switch, and the second pre-charge switch comprises a transistor.
